(19) United States
(12) Patent Application Publication
(10) Pub. No.: US 2002/0024125 A1
(43) Pub. Date: Feb. 28, 2002

(54) Semiconductor device and method for assembling the same

(75) Inventor: Kazutaka Shibata, Kyoto (JP)

Correspondence Address: RADER FISHMAN & GRAUER PLLC, LION BUILDING, 1233 20TH STREET N.W., SUITE 501, WASHINGTON, DC, 20036, US

(73) Assignee: ROHM CO., LTD.

(21) Appl. No.: 09/812,584

(22) Filed: Jul. 26, 2001

(30) Foreign Application Priority Data
Mar. 21, 2000 (JP) 2000-78655

(51) Int. Cl. H01L 23/02

(52) U.S. Cl. 257/678

(57) ABSTRACT

A semiconductor device having a plurality of semiconductor chips joined to a surface of a solid. The plurality of semiconductor chips differ in the height from the surface of the solid. The semiconductor device can be assembled by joining the semiconductor chips to the surface of the solid in the order of their increasing heights.

### BACKGROUND OF THE INVENTION

1. Field of the Invention

The present invention relates to a semiconductor device having a structure in which a plurality of semiconductor chips are joined to a surface of a solid (a surface of a wiring board or a semiconductor chip).

2. Description of Related Art

Known as one form of a so-called multi-chip type semiconductor device is a chip-on-chip structure in which a plurality of semiconductor chips are overlapped with one another. In the semiconductor device having a chip-on-chip structure, joined to a surface of a primary chip externally connected is a secondary chip smaller than the primary chip. In this case, a plurality of secondary chips may, in some cases, be joined to the surface of the primary chip.

Known as another form of the multi-chip type semiconductor device is a structure in which a plurality of semiconductor chips are joined to a wiring board in high density.

In the case the semiconductor device has either one of the structures, the substantial integration degree of the semiconductor device can be improved by mounting a lot of semiconductor chips in high density. Consequently, it is preferable that the semiconductor chips arranged on the primary chip or the wiring board are joined with a distance therebetween made as short as possible.

For example, the multi-chip type semiconductor device having the chip-on-chip structure is assembled by successively joining the plurality of secondary chips to the surface of the primary chip. In this case, the secondary chip is joined to the surface of the primary chip using a chip holding head called a suction collet. The suction collet vacuum-sucks an inactive surface, for example, of the secondary chip to hold the secondary chip, introduces the secondary chip into the surface of the primary chip, and presses the secondary chip against the surface of the primary chip. At this time, bumps respectively formed on the surfaces of the secondary chip and the primary chip are joined upon being pressed against each other. Consequently, electrical and mechanical connections between the primary chip and the secondary chips are achieved.

The sizes of the secondary chips joined to the surface of the primary chip are not uniform. However, the size of the suction collet cannot be made to differ for each secondary chip. Therefore, the suction collet is generally constructed in conformity with the relatively large secondary chip in many cases. The reason for this is that when the small suction collet is used, an external force from the suction collet is concentrated on a part of the secondary chip when the secondary chip is pressed against the primary chip, which may degrade the characteristics of and damage the secondary chip.

Particularly in a case where an attempt to arrange the secondary chips at positions in significantly close proximity to each other is made, when a suction surface of the suction collet is larger than secondary chip sucked by the suction collet, the suction collet may, in some case, interfere with the other secondary chips which have already been joined to the primary chip.

### SUMMARY OF THE INVENTION

An object of the present invention is to provide a semiconductor device having a structure in which a plurality of semiconductor chips can be satisfactorily joined to a surface of a solid and a method of assembling the same.

The present invention relates to a semiconductor device in which a plurality of semiconductor chips are joined to a surface of a solid. The semiconductor device is so constructed that the plurality of semiconductor chips differ in the heights from the surface of the solid.

The semiconductor device can be assembled by joining the semiconductor chips to the surface of the solid in the order of their increasing heights.

According to the present invention, the plurality of semiconductor chips which are joined to the surface of the solid are made to differ in the height. In joining the plurality of semiconductor chips to the surface of the solid, if the semiconductor chips are joined to the surface of the solid in the order of their increasing heights, a chip holding mechanism used in joining the semiconductor chips to the surface of the solid does not interfere with the semiconductor chips which have already been joined to the surface of the solid.

Consequently, the plurality of semiconductor chips can be arranged on the surface of the solid in significantly close proximity to each other. Accordingly, it is possible to realize a semiconductor device having a plurality of semiconductor chips mounted thereon in high density.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an illustrative sectional view for explaining the construction of a semiconductor device according to an embodiment of the present invention; and

FIG. 2 is an illustration for explaining a method of assembling the semiconductor device.

### DESCRIPTION OF THE PREFERRED EMBODIMENTS

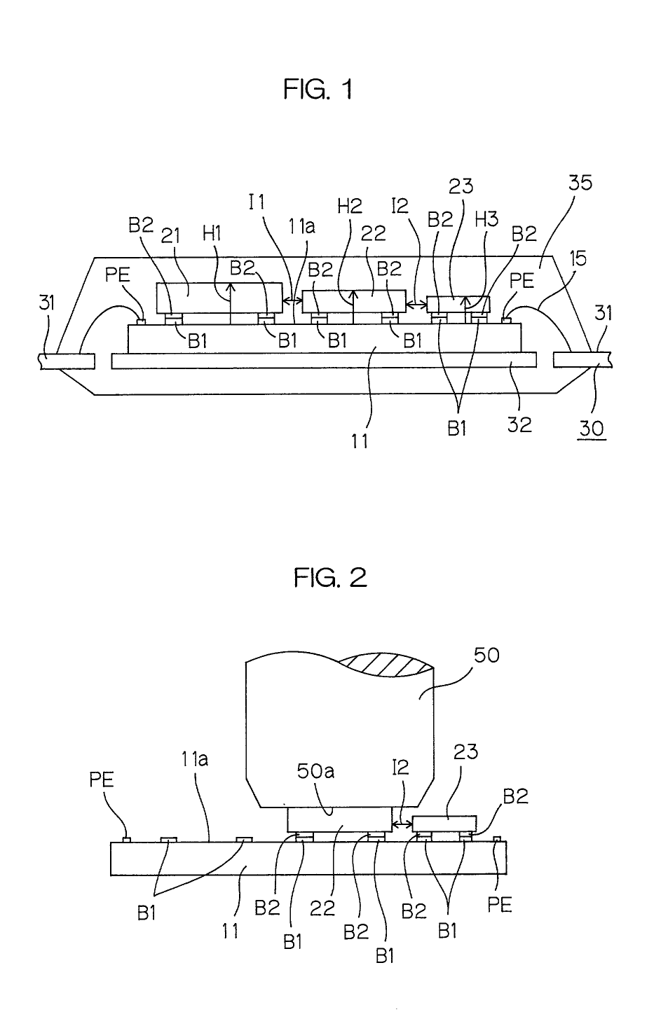

FIG. 1 is an illustrative sectional view for explaining the construction of a semiconductor device according to an embodiment of the present invention. The semiconductor device is a multi-chip type semiconductor device having a chip-on-chip structure in which secondary chips 21, 22, and 23 serving as a plurality of semiconductor chips are joined to an active surface 11a of a primary chip 11 serving as a solid device. That is, the primary chip 11 has a plurality of bumps B1 for inter-chip connection with the secondary chips 21, 22, and 23 formed on its active surface 11a. Further, a plurality of external connection pads PE for external connection are provided in a peripheral edge region of the active surface 11a.

On the other hand, the secondary chips 21, 22, and 23 have bumps B2 for inter-chip connection with the primary chip 11 respectively formed on their active surfaces. The bumps B2 on the secondary chips 21, 22, and 23 are respectively joined to the bumps B1 on the primary chip 11, thereby achieving electrical and mechanical bonds between the primary chip 11 and the secondary chips 21, 22, and 23.

The external connection pad PE provided on the active surface 11a of the primary chip 11 is connected to a terminal portion 31 of a lead frame 30 by a bonding wire 15. The lead frame 30 has an island portion 32 to which the primary chip 11 is die-bonded and the terminal portion 31 connected to a mounting board or the like in electronic equipment.

The primary chip 11, the secondary chips 21, 22, and 23, the bonding wire 15, and a part of the terminal portion 31 of the lead frame 30 are sealed in molding resin 35. The terminal portion 31 is extended out of the molding resin 35, and a portion, extended out of the molding resin 35, of the terminal portion 31 is connected to the mounting board, for example, with solder.

The plurality of secondary chips 21, 22, and 23 differ in heights H1, H2, and H3 from the active surface 11a of the primary chip 11. That is, the height H1 of the secondary chip 21 is the largest, the height H2 of the secondary chip 22 is the second largest, and the height H3 of the secondary chip 23 is the smallest of the three secondary chips.

FIG. 2 is a diagram for explaining a method of assembling the semiconductor device, which illustratively shows how the secondary chips 21, 22, and 23 are joined to the primary chip 11. The plurality of secondary chips 21, 22, and 23 are joined to the active surface 11a of the primary chip 11 in the order of their increasing heights. At this time, the secondary chips 21, 22, and 23 are held with their inactive surfaces sucked by a suction collet 50 which is a chip holding head, are taken out of a chip holding tray, and are introduced into the active surface 11a of the primary chip 11.

In joining the plurality of secondary chips 21, 22, and 23, the suction collet 50 first joins the lowest secondary chip 23 to the active surface 11a of the primary chip 11. The suction collet 50 then takes out the second lowest secondary chip 22 from the chip holding tray, and joins the secondary chip 22 to the active surface 11a of the primary chip 11. Finally, the suction collet 50 takes out the highest secondary chip 21 from the chip holding tray, and joins the secondary chip 21 to a predetermined portion on the active surface 11a of the primary chip 11.

The suction collet 50 comprises a slightly larger suction surface 50a than the secondary chip 21 having the largest area, for example. This is for preventing pressure from being locally applied to any portions of the inactive surfaces of the secondary chips 21, 22, and 23. In this case, when the suction collet 50 sucks the relatively small secondary chips 22 and 23, the suction surface 50a greatly juts out of the inactive surfaces of the secondary chips 22 and 23. In this case, if the highest secondary chip 21 is joined to the primary chip 11 prior to the secondary chips 22 and 23, the suction collet 50 and the secondary chip 21 interfere with each other when the secondary chip 22 adjacent to the secondary chip 21 is joined to the primary chip 11. Consequently, a large force is locally applied to the secondary chip 21. Therefore, the characteristics of the secondary chip 21 may be degraded, and the secondary chip 21 may be damaged and separated from the primary chip 11.

In the present embodiment, therefore, the plurality of secondary chips 21, 22, and 23 are previously made to differ in the height so that the secondary chips are joined to the active surface 11a of the primary chip 11 in the order of their increasing heights. Even if the secondary chips 21, 22, and 23 are joined with distances I1 and I2 therebetween made significantly short, the suction collet 50 may not interfere with any one of the secondary chips at the time of the joining.

Although description has been made of an embodiment of the present invention, the present invention can be embodied in another mode. That is, although in the above-mentioned embodiment, the chip-on-chip structure in which the secondary chips 21, 22, and 23 are joined to the primary chip 11 is taken as an example, the present invention is also applicable to a multi-chip type semiconductor device in which a plurality of semiconductor chips are mounted on a wiring board in high density.

Although description has been made of such construction that the secondary chips 21, 22, and 23 are joined to active surface 11a of the primary chip 11 by so-called face-down bonding with their respective active surfaces opposed to the active surface 11a, the secondary chips 21, 22, and 23 may be joined to the active surface 11a of the primary chip 11 using adhesives, for example, with their respective inactive surfaces on the opposite side of the active surfaces opposed to the active surface 11a (face-up joining). In this case, pads for inter-chip connection are provided on the active surfaces of the secondary chips 21, 22, and 23. The pad may be electrically connected, respectively, to pads for inter-chip connection provided on the active surface 11a of the primary chip 11 by wire bonding.

Although the present invention has been described and illustrated in detail, it is clearly understood that the same is by way of illustration and example only and is not to be taken by way of limitation, the spirit and scope of the present invention being limited only by the terms of the appended claims.

This application corresponds to Japanese Patent Application No. 2000-78655 filed with the Japanese Patent Office on Mar. 21, 2000, the disclosure of which is incorporated herein by reference.

What is claimed is:

1. A semiconductor device in which a plurality of semiconductor chips are joined to a surface of a solid, wherein
the plurality of semiconductor chips differ in height from the surface of the solid.

2. A method of assembling a semiconductor device by joining a plurality of semiconductor chips to a surface of a solid, comprising the steps of:
preparing a plurality of semiconductor chips which differ in height; and
joining the semiconductor chips to the surface of the solid in the order of their increasing heights.
